(19) United States
(12) Patent Application Publication
(10) Pub. No.: US 2008/0265950 A1
(43) Pub. Date: Oct. 30, 2008

(54) LOW-POWER IMPEDANCE-MATCHED DRIVER

(76) Inventors: Scott Gary Sorenson, Lakeville, MN (US); Jeremy Robert Kuehlwein, Woodburry, MN (US)

Correspondence Address: TEXAS INSTRUMENTS INCORPORATED, P O BOX 655474, M/S 3999, DALLAS, TX, 75265, US

(21) Appl. No.: 12/102,110

(22) Filed: Apr. 14, 2008

Related U.S. Application Data
(60) Provisional application No. 60/913,170, filed on Apr. 20, 2007.

(51) Int. Cl. H03K 3/01

(52) U.S. Cl. 327/108

(57) ABSTRACT

One embodiment of the invention includes a driver circuit. The driver circuit comprises a high-side switch that is activated in response to a positive driver input signal to provide a positive output signal at a driver output. The driver circuit also comprises a low-side switch that is activated in response to a negative driver input signal to provide a negative output signal at the driver output. The positive and negative driver input and output signals can be relative to respective cross-over magnitudes. The driver circuit further comprises at least one impedance-matching device configured to activate the low-side switch in response to a positive signal reflection at the driver output and to activate the high-side switch in response to a negative signal reflection at the driver output.

### RELATED APPLICATIONS

The present invention claims priority from U.S. Provisional Patent Application No. 60/913,170, filed Apr. 20, 2007, entitled: “Low Power, High Speed Matched Load Write Driver”.

### TECHNICAL FIELD

This invention relates to electronic circuits, and more specifically to a low-power impedance-matched driver.

### BACKGROUND

Driver circuits are used in numerous applications. As an example, driver circuits such as any of a variety of classes of amplifiers, can be implemented in the transmission of data to a different medium, such as for wireless transmission or for writing data to a magnetic medium. In order to obtain a relatively constant gain over the specified bandwidth of a driver, it is desirable to match the output impedance of the driver with the input impedance of the load and/or the transmission line impedance of the transmission line that interconnects the driver and the load. If a significant impedance mismatch exists, signal reflections at the output of the driver caused by the impedance mismatch will compromise the performance of the system. In such a situation, a signal output from the driver will be degraded or noisy at signal transitions, consequently narrowing the bandwidth over which the system can effectively operate.

One type of driver is a class AB driver. As an example, a class AB driver can include biasing components that can make operation of the driver more linear. As such, the class AB driver may not experience cross-over distortion when the input signal transitions from low values to high values, or vice verse. However, a tail current, such as flowing from a positive power rail to a negative power rail, can be large, and can thus consume a significant amount of power.

### SUMMARY

One embodiment of the invention includes a driver circuit. The driver circuit comprises a high-side switch that is activated in response to a positive driver input signal to provide a positive output signal at a driver output. The driver circuit also comprises a low-side switch that is activated in response to a negative driver input signal to provide a negative output signal at the driver output. The positive and negative driver input and output signals can be relative to respective cross-over magnitudes. The driver circuit further comprises at least one impedance-matching device configured to activate the low-side switch in response to a positive signal reflection at the driver output and to activate the high-side switch in response to a negative signal reflection at the driver output.

Another embodiment of the invention includes a driver circuit. The driver circuit comprises a high-side switch that is activated in response to a positive driver input signal to provide a positive output signal at a driver output. The driver circuit also comprises a low-side switch that is activated in response to a negative driver input signal to provide a negative output signal at the driver output. The positive and negative driver input and output signals can be relative to respective cross-over magnitudes. The driver circuit further comprises a first impedance-matching device interconnecting the high-side switch and the driver output and a second impedance-matching device interconnecting the low-side switch and the driver output.

Another embodiment of the invention includes a driver circuit. The driver circuit comprises means for providing a positive output signal at a driver output in response to a driver input signal having a magnitude that is greater than a first voltage. The first voltage can be greater than an input cross-over voltage. The driver circuit also comprises means for providing a negative output signal at the driver output in response to the driver input signal having a magnitude that is less than a second voltage. The second voltage can be less than the input cross-over voltage. The positive and negative output signals can be relative to an output cross-over voltage. The driver circuit further comprises means for substantially matching an output impedance of the driver output with one of a load and an interconnecting transmission line and for setting respective magnitudes of the first voltage and the second voltage.

### BRIEF DESCRIPTION OF THE DRAWINGS

FIG. 1 illustrates an example of a signal driver system in accordance with an aspect of the invention.

FIG. 2 illustrates an example of a driver circuit in accordance with an aspect of the invention.

FIG. 3 illustrates an example of a timing diagram of a driver circuit in accordance with an aspect of the invention.

FIG. 4 illustrates an example of a diagram demonstrating an effect of an output signal reflection in accordance with an aspect of the invention.

FIG. 5 illustrates another example of a diagram demonstrating an effect of an output signal reflection in accordance with an aspect of the invention.

FIG. 6 illustrates an example of a magnetic disk write system in accordance with an aspect of the invention.

### DETAILED DESCRIPTION

The invention relates to electronic circuits, and more specifically to a low-power impedance-matched driver. The low-power impedance-matched driver can be configured, for example, as a pseudo-impedance-matched form of a class AB driver. The driver includes a high-side switch and a low-side switch to reproduce an input signal at the driver output. The driver can also include impedance-matching devices, such as resistors, between the high-side switch and the output and the low-side switch and the output. The impedance-matching devices can thus create an input signal dead-band, such that at least one of the high and low-side switches is deactivated absent a signal reflection to substantially mitigate power consumption by substantially eliminating a tail current.

The driver circuit can also implement effective impedance-matching. Specifically, signal reflections at the driver output change the bias level of a respective one of the high or low-side switch based on the voltage across the impedance-matching devices. As a result, the high or low-side switch activates to either source current to a negative signal reflection or sink current from a positive signal reflection, respectively, to dissipate the signal reflection. Thus, current flows through the high and low-side switches only when necessary to provide the output signal and/or to terminate signal reflections.

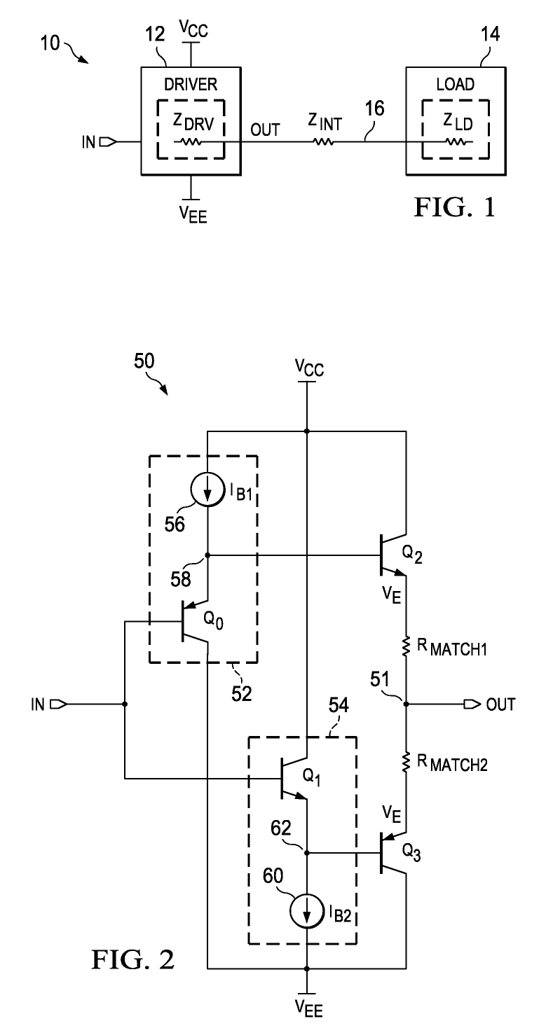

FIG. 1 illustrates an example of a signal driver system 10 in accordance with an aspect of the invention. The signal driver system 10 includes a signal driver 12 coupled to a load 14 via transmission line 16. The signal driver 12 is demonstrated in the example of FIG. 1 as being interconnected between a positive rail voltage V_{CC} and a negative rail voltage V_{EE}. The signal driver 12 can include any of a variety of driver circuits, such as a class AB driver. Therefore, the signal driver 12 can be configured to receive an input signal IN and provide an output signal OUT, such that the output signal OUT can be a buffered and/or amplified version of the input signal IN. The transmission line 16 transmits the output signal OUT from the signal driver 12 to the load 14. The load 14 can be any of a variety of devices that implement the buffered/amplified output signal OUT, such as an inductive load utilized in a magnetic disk write system.

In the example of FIG. 1, the impedance of the signal driver 12 is demonstrated as Z_{DRV}, the impedance of the load 14 is demonstrated as Z_{LD}, and the impedance of the transmission line 16 is demonstrated as Z_{INT}. In order to mitigate signal reflections, it may be desirable to substantially match the impedance Z_{DRV} of the signal driver 12 to the impedance Z_{INT} of the transmission line 16. Likewise, it may be desirable to substantially match the input impedance Z_{LD} of the load 14 to the impedance Z_{INT} of the transmission line 16. Properly matching the impedance Z_{DRV} with the impedances Z_{INT} and/or Z_{LD} can substantially mitigate the deleterious effects of signal reflections of the output signal provided from the signal driver 12 back to an output of the signal driver 12. Therefore, the signal driver 12 is configured to include one or more impedance-matching devices, such as resistive components, to provide an appropriate impedance-match of the impedance Z_{DRV} with the impedances Z_{INT} and/or Z_{LD}. In addition, in providing the appropriate impedance-matching, the signal driver 12 is configured to mitigate power consumption, such as based on a tail current that flows from the positive rail voltage V_{CC} to the negative rail voltage V_{EE}.

FIG. 2 illustrates an example of a driver circuit 50 in accordance with an aspect of the invention. The driver circuit 50 can correspond to the signal driver 12 in the example of FIG. 1. Therefore, the driver circuit 50 receives an input signal IN and provides an output signal OUT at an output 51 onto transmission lines to a load, such as to a magnetic disk write head. Accordingly, reference is to be made to the example of FIG. 1 in the following discussion of the example of FIG. 2.

The driver circuit 50 interconnects a positive rail voltage V_{CC} and a negative rail voltage V_{EE}. As an example, the voltage range between the positive rail voltage V_{CC} and the negative rail voltage V_{EE} can be substantially centered at ground. As such, the positive rail voltage V_{CC} can be positive relative to ground and the negative rail voltage V_{EE} can be negative relative to ground. Therefore, as described in greater detail below, the input signal IN and the output signal OUT can be positive and negative pulses relative to a cross-over voltage that is approximately zero volts. However, it is to be understood that the cross-over voltage is not limited to being zero volts, such that the input pulses can be between any of a variety of voltage ranges (e.g., 0-5 volts).

The driver circuit 50 includes a first bias circuit 52 and a second bias circuit 54 that are each coupled to the input signal IN. The first bias circuit 52 includes a first current source 56 and a PNP-type bipolar junction transistor (BJT) Q₀. The first current source 56 provides a current I_{B1} from the positive rail voltage V_{CC} to a first bias node 58. The transistor Q₀ is biased by the input signal IN and has a collector that is coupled to the negative rail voltage V_{EE} and an emitter that is coupled to the first bias node 58. Therefore, the transistor Q₀ is substantially configured as an emitter-follower with respect to the input signal IN. As an example, the first bias node 58 can have a magnitude that is approximately a “diode-drop” (i.e., activation voltage or approximately 0.7 volts) above the magnitude of the input signal IN. As a result, the first bias node 58 has a voltage magnitude that substantially follows the input signal IN, such that the voltage magnitude of the first bias node 58 decreases as the magnitude of the input signal IN decreases and increases as the magnitude of the input signal IN increases.

The second bias circuit 54 includes a second current source 60 and an NPN-type transistor Q₁. The second current source 60 provides a current I_{B2} to the negative rail voltage V_{EE} from a second bias node 62. The transistor Q₁ is biased by the input signal IN and has a collector that is coupled to the positive rail voltage V_{CC} and an emitter that is coupled to the second bias node 62. Therefore, similar to the transistor Q₀, the transistor Q₁ is likewise substantially configured as an emitter-follower with respect to the input signal IN. As an example, the second bias node 62 can have a magnitude that is approximately a “diode drop” below the magnitude of the input signal IN. As a result, the second bias node 62 has a voltage magnitude that likewise substantially follows the input signal IN, such that the voltage magnitude of the second bias node 62 decreases as the magnitude of the input signal IN decreases and increases as the magnitude of the input signal IN increases.

The driver circuit 50 also includes a high-side switch and a low-side switch, demonstrated in the example of FIG. 2 as an NPN-type transistor Q₂ and a PNP-type transistor Q₃, respectively. The transistor Q₂ is biased by the first bias node 58 and has a collector coupled to the positive rail voltage V_{CC}. The transistor Q₃ is biased by the second bias node 62 and has a collector coupled to the negative rail voltage V_{EE}. The transistor Q₂ is thus configured to source current from the positive rail voltage V_{CC} to the output 51 and the transistor Q₃ is thus configured to sink current from the output 51 to the negative rail voltage V_{EE}.

Specifically, in the example of FIG. 2, the transistor Q₂ is thus substantially configured as an emitter-follower with respect to the first bias node 58 and the transistor Q₃ is substantially configured as an emitter-follower with respect to the second bias node 62. Therefore, an emitter voltage V_{E} of the transistor Q₂ substantially follows the voltage magnitude of the first bias node 58 minus an approximate diode-drop voltage, and an emitter voltage V_{E} of the transistor Q₃ substantially follows the voltage magnitude of the second bias node 62 plus an approximate diode-drop voltage. In addition, it is to be understood that a current gain of the output signal OUT can be realized relative to the input signal IN based on size characteristics associated with the transistors Q₂ and Q₃ relative to the transistors Q₀ and Q₁.

The driver circuit 50 further includes a first impedance-matching device, demonstrated in the example of FIG. 2 as a resistor R_{MATCH1}, and a second impedance-matching device, demonstrated in the example of FIG. 2 as a resistor R_{MATCH2}. The resistors R_{MATCH1} and R_{MATCH2} interconnect emitters of the respective transistors Q₂ and Q₃ with the output 51. At increasing magnitudes of the input signal IN, the voltage at the first bias node 58 increases. In response, the transistor Q₂ activates to source current from the positive rail voltage V_{CC} through the resistor R_{MATCH1} to the output 51, such that the output signal OUT likewise has an increasing magnitude. Similarly, at decreasing magnitudes of the input signal IN, the voltage at the second bias node 62 decreases. In response, the transistor Q₃ activates to sink current from the output 51 through the resistor R_{MATCH2} to the negative rail voltage V_{EE}, such that the output signal OUT likewise has a decreasing magnitude.

The first and second resistors R_{MATCH1} and R_{MATCH2} are configured to provide impedance-matching of the output 51 to a load or an interconnecting transmission line, such as the load 14 or the transmission line 16. As an example, the first and second resistors R_{MATCH1} and R_{MATCH2} can each have a resistance value that is selected to be approximately equal to an impedance value of an associated connected load and/or interconnecting transmission line (e.g., 70 ohms). In addition, as described in greater detail below, the resistors R_{MATCH1} and R_{MATCH2} are configured to substantially terminate negative and positive signal reflections, respectively, that are received at the output 51, such as received from a mismatched load that is coupled to an opposite end of a transmission line connected to the output 51.

As described herein, it is to be understood that termination of signal reflections is defined as the matching of an impedance of the output 51 of the driver circuit 50 and providing the ability to sink or source current associated with the signal reflections through an appropriately matched impedance. As a result, there is substantially no positive or negative signal reflection from the output 51 of the driver circuit 50 back to the coupled load and/or back down the coupled transmission line. In addition, it is to be understood that, for purposes of the discussion of the example of FIG. 2 herein, the resistors R_{MATCH1} and R_{MATCH2} have approximately equal resistance values and the transistors Q₂ and Q₃ are configured substantially the same (e.g., substantially similar operating characteristics). However, it is also to be understood that the driver circuit 50 is not limited to substantial uniformity between the resistors R_{MATCH1} and R_{MATCH2} and the transistors Q₂ and Q₃.

As demonstrated in the example of FIG. 2, the location of the resistors R_{MATCH1} and R_{MATCH2} affects the bias levels of the respective transistors Q₂ and Q₃ to effect termination of signal reflections. Specifically, the first and second resistors R_{MATCH1} and R_{MATCH2} are configured as degeneration resistors. As such, the resistor R_{MATCH1} increases the emitter voltage V_{E} of the transistor Q₂ relative to the output 51 and the resistor R_{MATCH2} decreases the emitter voltage V_{E} of the transistor Q₃ relative to the output 51. As a result, a greater voltage at the first bias node 58 relative to the output signal OUT is required to activate the transistor Q₂ and a lesser voltage at the second bias node 62 relative to the output signal OUT is required to activate the transistor Q₃ with the respective first and second resistors R_{MATCH1} and R_{MATCH2} than would be required without them. Accordingly, the first and second resistors R_{MATCH1} and R_{MATCH2} are configured to set a dead-band voltage associated with the input signal that is substantially centered at the cross-over voltage of the input signal IN.

It is to be understood that the driver circuit 50 is not intended to be limited to the example of FIG. 2. As an example, the transistors Q₀ through Q₃ are not limited to BJTs, but can instead be implemented as field effect transistors (FETs). In addition, the bias circuits 52 and 54 can be configured in any of a variety of ways to provide the bias voltages to the bases of the transistors Q₂ and Q₃. Accordingly, the driver circuit 50 can be configured in any of a variety of ways.

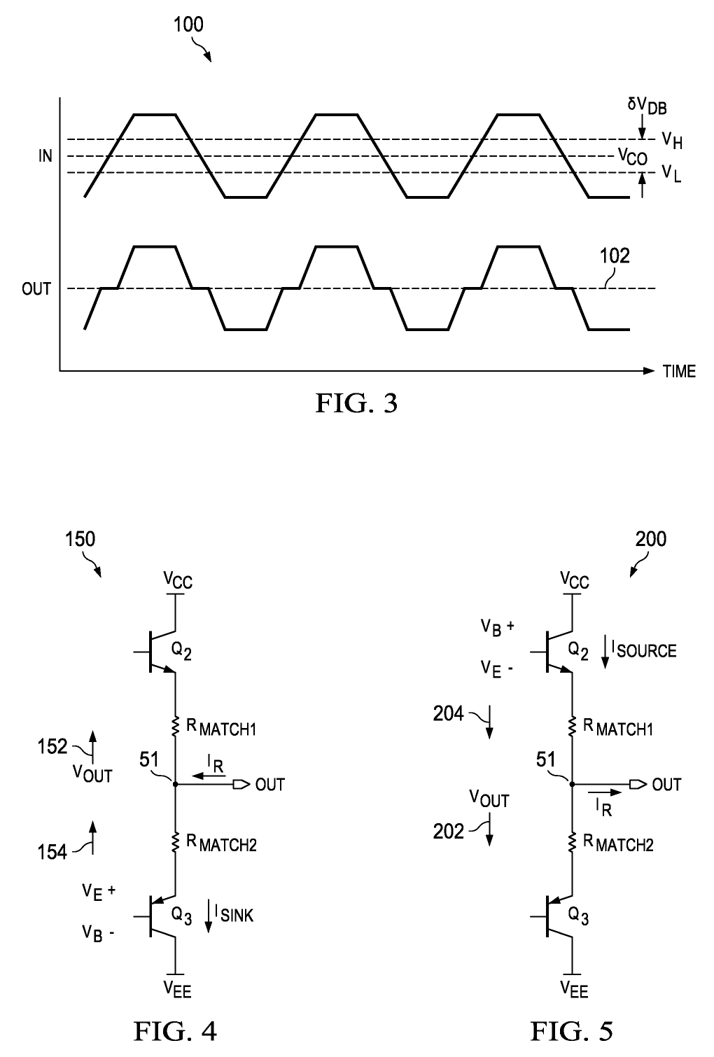

FIG. 3 illustrates an example of a timing diagram 100 of the driver circuit 50 in accordance with an aspect of the invention. The timing diagram 100 demonstrates the input signal IN and the output signal OUT as a function of time. In the example of FIG. 3, the input signal IN is demonstrated as repeated positive and negative pulses relative to a cross-over voltage V_{CO}. The timing diagram 100 also demonstrates a voltage V_{H} having a magnitude that is greater than the cross-over voltage V_{CO} and a voltage V_{L} having a magnitude that is less than the cross-over voltage V_{CO}. The voltage V_{H} is representative of a voltage magnitude of the input signal IN at which the high-side switch (i.e., the transistor Q₂) activates to source current from the positive rail voltage V_{CC} to the output 51. Similarly, the voltage V_{L} is representative of a voltage magnitude of the input signal IN at which the low-side switch (i.e., the transistor Q₃) activates to sink current from the output 51 to the negative rail voltage V_{EE}.

In the example of FIG. 3, the voltage V_{H} and the voltage V_{L} collectively represent a dead-band voltage range δV_{DB}. Specifically, the dead-band voltage range δV_{DB} is the range of voltages between the voltage V_{H} and the voltage V_{L}, and is substantially centered at the cross-over voltage V_{CO}. As a result, for a magnitude of the input signal IN greater than the voltage V_{H}, the transistor Q₂ is activated while the transistor Q₃ remains deactivated, and for a magnitude of the input signal IN less than the voltage V_{L}, the transistor Q₃ is activated while the transistor Q₂ remains deactivated. However, for a magnitude of the input signal IN that is within the dead-band voltage range δV_{DB}, neither the transistor Q₂ nor the transistor Q₃ is activated. Thus, the dead-band voltage range δV_{DB} generates cross-over distortion, such that the output signal OUT has a non-linear response relative to the input signal IN at values of the output signal OUT substantially near a cross-over magnitude 102 of the output signal OUT.

As thus demonstrated in the examples of FIGS. 2 and 3, based on the dead-band voltage range δV_{DB} that is set by the resistors R_{MATCH1} and R_{MATCH2}, current flows from the positive rail voltage V_{CC} to the output 51 or from the output 51 to the negative rail voltage V_{EE} substantially only when necessary to maintain the output signal OUT. In other words, there is substantially no current flow from the positive rail voltage V_{CC} to the negative rail voltage V_{EE} through the transistors Q₂ and Q₃ because the transistors Q₂ and Q₃ are not activated concurrently during typical operating conditions of the driver circuit 50. As a result, power consumption of the driver circuit 50 is substantially very efficient, as there is no wasteful tail current flow through the driver circuit 50.

In addition to substantially mitigating power consumption, the dead-band voltage range δV_{DB} that is set by the resistors R_{MATCH1} and R_{MATCH2} also effectively provides impedance-matching of the output 51 with respect to a load and/or an interconnecting transmission line. As an example, the resistors R_{MATCH1} and R_{MATCH2} are configured to substantially terminate the effects of signal reflections received at the output 51, such as from the load and/or the interconnecting transmission line. Specifically, the resistors R_{MATCH1} and R_{MATCH2} affect the bias levels of the respective transistors Q₂ and Q₃ based on the voltage difference across the resistors R_{MATCH1} and R_{MATCH2} in response to respective negative and positive signal reflections. As an example, in response to a positive signal reflection, the transistor Q₃ activates to sink the positive signal reflection to the negative rail voltage V_{EE} through the second resistor R_{MATCH2}. Similarly, in response to a negative signal reflection, the transistor Q₂ activates to source current to the negative signal reflection from the positive rail voltage V_{CC} through the first resistor R_{MATCH1}.

FIG. 4 illustrates an example of a diagram 150 demonstrating an effect of an output signal reflection in accordance with an aspect of the invention. The diagram 150 demonstrates a portion of the driver circuit 50 in the example of FIG. 2. Specifically, the diagram 150 demonstrates the transistors Q₂ and Q₃, the resistors R_{MATCH1} and R_{MATCH2}, and the output 51. Thus, reference is to be made to the examples of FIGS. 1 and 2 in the following discussion of the example of FIG. 4.

In the example of FIG. 4, a positive signal reflection is demonstrated at the output 51 by a current I_{R} flowing into the output 51, such as from the load 14 and/or the transmission lines 16. Because the current I_{R} is a positive current based on flowing into the output 51, a voltage magnitude V_{OUT} at the output 51 begins to increase, as demonstrated by an arrow 152. Therefore, the emitter voltage V_{E} of the transistor Q₃ likewise begins to increase, as demonstrated by an arrow 154, relative to the base voltage V_{B} of the transistor Q₃. Thus, the magnitude of the base-emitter voltage V_{BE} of the transistor Q₃ increases based on the magnitude of the current I_{R}. Accordingly, the transistor Q₃ activates to sink the current I_{R} substantially entirely from the output 51 through the second resistor R_{MATCH 2}, as demonstrated in the example of FIG. 4 by the transistor Q₃ conducting a current I_{SINK}. The current I_{SINK} thus substantially terminates the positive signal reflection current I_{R} based on the matched resistance value of the second resistor R_{MATCH2}, such that substantially no portion of the current I_{R} is reflected back from the output 51.

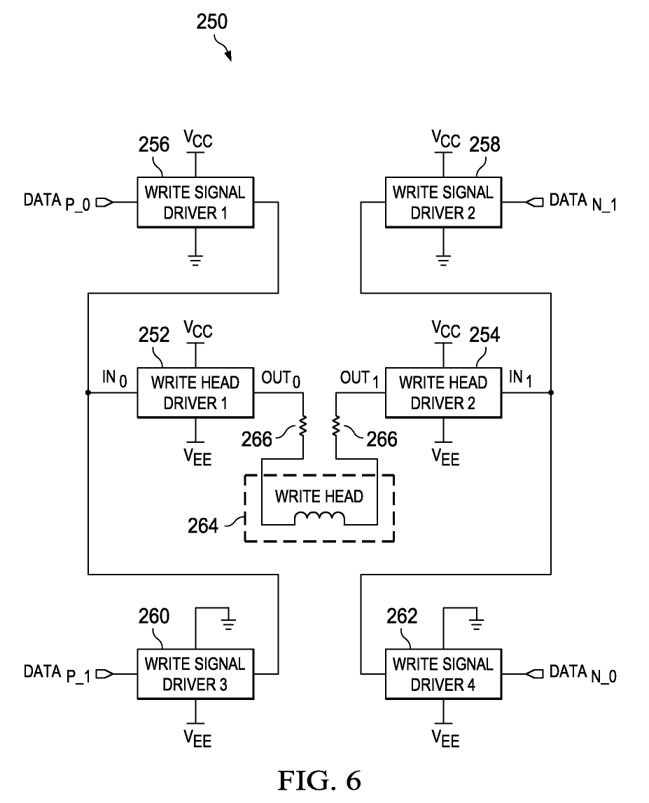

FIG. 5 illustrates another example of a diagram 200 demonstrating an effect of an output signal reflection in accordance with an aspect of the invention. The diagram 200 demonstrates a portion of the driver circuit 50 in the example of FIG. 2. Specifically, the diagram 200 demonstrates the transistors Q₂ and Q₃, the resistors R_{MATCH1} and R_{MATCH2}, and the output 51. Thus, reference is also to be made to the examples of FIGS. 1 and 2 in the following discussion of the example of FIG. 5.

In the example of FIG. 5, a negative signal reflection is demonstrated at the output 51 by a current I_{R} flowing from the output 51, such as to the load 14 and/or the transmission lines 16. Because the current I_{R} is a negative current with respect to the output 51, based on the current I_{R} flowing from the output 51, a voltage magnitude V_{OUT} at the output 51 begins to decrease, as demonstrated by an arrow 202. Therefore, the emitter voltage V_{E} of the transistor Q₂ likewise begins to decrease, as demonstrated by an arrow 204, relative to the base voltage V_{B} of the transistor Q₂. Thus, the magnitude of the base-emitter voltage V_{BE} of the transistor Q₂ increases based on the magnitude of the current I_{R}. Accordingly, the transistor Q₂ activates to source current through the first resistor R_{MATCH1} to the output 51 that is approximately equal to the current I_{R}, as demonstrated in the example of FIG. 5 by the transistor Q₂ conducting a current I_{SOURCE}. The current I_{SOURCE} thus substantially terminates the negative signal reflection current I_{R} based on the matched resistance value of the first resistor R_{MATCH1}, such that substantially no portion of the current I_{R} is reflected back to the output 51.

FIG. 6 illustrates an example of a magnetic disk write system 250 in accordance with an aspect of the invention. As an example, the magnetic disk write system 250 can be configured to write data to a hard-drive of a computer, or to a peripheral magnetic storage medium. The magnetic disk write system 250 includes a first write head driver 252 and a second write head driver 254, each of which can be configured substantially similar to the driver circuit 50 in the example of FIG. 2. Accordingly, reference is to be made to the example of FIG. 2 in the following discussion of the example of FIG. 6.

The system 250 includes a first write signal driver 256, a second write signal driver 258, a third write signal driver 260, and a fourth write signal driver 262. The first write signal driver 256 interconnects a positive rail voltage V_{CC} and ground, and receives a data signal DATA_{P}_{_{—}}₀ as an input. The second write signal driver 258 interconnects the positive rail voltage V_{CC} and ground, and receives a data signal DATA_{N}_{_{—}}₁ as an input. The third write signal driver 260 interconnects ground and a negative rail voltage V_{EE}, and receives a data signal DATA_{P}_{_{—}}₁ as an input. The fourth write signal driver 262 interconnects ground and the negative rail voltage V_{EE}, and receives a data signal DATA_{N}_{_{—}}₀ as an input. As an example, the data signals DATA_{P}_{_{—}}₀, DATA_{P}_{_{—}}₁, DATA_{N}_{_{—}}₀, and DATA_{N}_{_{—}}₁ can collectively correspond to a data signal DATA that represents a digital data stream to be written to a magnetic storage medium (not shown).

For example, the data signals DATA_{P}_{_{—}}₀ and DATA_{N}_{_{—}}₀ can have opposite logic states at a given time to activate the respective first and fourth write signal drivers 256 and 262 concurrently. Similarly, the data signals DATA_{P}_{_{—}}₁ and DATA_{N}_{_{—}}₁ can have opposite logic states at a given time to activate the respective second and third write signal drivers 258 and 260 concurrently. The logic states of the data signals DATA_{P}_{_{—}}₀, DATA_{P}_{_{—}}₀, DATA_{N}_{_{—}}₀, and DATA_{N}_{_{—}}₁ thus control logic states of input signals IN₀ and IN₁, which are respective input signals of the first and second write head drivers 252 and 254. Accordingly, the first and second write head drivers 252 and 254 can generate respective output signals OUT₀ and OUT₁ to provide current flow through a write head 264 via transmission lines 266. As an example, the write head 264 can include an inductive load to generate a magnetic field in response to the current flow. As a result, the magnetic field can set a polarity of portions of the magnetic medium, such as the magnetic disk, to correspond to the data signal DATA.

As an example, the data signal DATA_{P}_{_{—}}₀ can be asserted (i.e., logic-high) and the data signal DATA_{N}_{_{—}}₀ can be de-asserted (i.e., logic-low) concurrently. At the same time, the data signal DATA_{P}_{_{—}}₁ can be asserted and the data signal DATA_{N}_{_{—}}₁ can be de-asserted concurrently. As a result, the first and fourth write signal drivers 256 and 262 can each be activated and the second and third write signal drivers 258 and 260 can each be deactivated. Therefore, the input signal IN₀ can be set at a logic-high state based on the activation of the first write signal driver 256 and the input signal IN₁ can be set at a logic-low state based on the activation of the fourth write signal driver 262. As a result, the output signal OUT₀ has a logic-high state and the output signal OUT₁ has a logic-low state. Accordingly, the first write head driver 252 provides current through the write head 264 from the positive rail voltage V_{CC}, which is thus sunk to the negative rail voltage V_{EE} through the second write head driver 254.

As another example, the data signal DATA_{P}_{_{—}}₁ can be de-asserted and the data signal DATA_{N}_{_{—}}₁ can be asserted concurrently. At the same time, the data signal DATA_{P}_{_{—}}₀ can be de-asserted and the data signal DATA_{N}_{_{—}}₀ can be de-asserted concurrently. As a result, the second and third write signal drivers 258 and 260 can each be activated and the first and fourth write signal drivers 256 and 262 can each be deactivated. Therefore, the input signal IN₁ can be set at a logic-high state based on the activation of the second write signal driver 258 and the input signal IN₀ can be set at a logic-low state based on the activation of the third write signal driver 260. As a result, the output signal OUT₁ has a logic-high state and the output signal OUT₀ has a logic-low state. Accordingly, the second write head driver 254 provides current through the write head 264 from the positive rail voltage V_{CC}, which is thus sunk to the negative rail voltage V_{EE} through the first write head driver 252.

As described above, the first and second write head drivers 252 and 254 can be configured substantially similar to the driver circuit 50 in the example of FIG. 2. As such, each of the first and second write head drivers 252 and 254 can include impedance-matching devices configured between respective high and low-side switches and the respective outputs that provide the output signals OUT₀ and OUT₁. As an example, the impedance-matching devices can have a resistance value that is substantially matched with an impedance value of the transmission lines 266. Therefore, bias levels of the high and low-side switches of each of the first and second write head drivers 252 and 254 can be affected to set a switching dead-band of the input signals IN₀ and IN₁, respectively. As a result, positive and negative signal reflections back to the first and second write head drivers 252 and 254 from the write head 264 can be substantially terminated, similar to as described above in the examples of FIGS. 4 and 5. Accordingly, positive and negative signals are likewise not reflected back onto the transmission lines 266 from the first and second write head drivers 252 and 254. In addition, power consumption can be conserved due to the mitigation of wasteful tail current flow through the high and low-side switches, similar to as described above.

It is to be understood that the magnetic disk write system 250 is not intended to be limited to the example of FIG. 6. As an example, the magnetic disk write system 250 is demonstrated in the example of FIG. 6 simplistically. As such, the magnetic disk write system 250 can include interconnections between the first through fourth write signal drivers 256 through 262 with respect to each other and additional interconnections with respect to the first and second write head drivers 252 and 254. In addition, other configurations of write signal drivers and write head drivers are possible for a given magnetic disk write system, such that the driver circuit 50 can be implemented in a different manner for a given magnetic disk write system. Accordingly, the magnetic disk write system 250 can be configured in any of a variety of ways.

What have been described above are examples of the invention. It is, of course, not possible to describe every conceivable combination of components or methodologies for purposes of describing the invention, but one of ordinary skill in the art will recognize that many further combinations and permutations of the invention are possible. Accordingly, the invention is intended to embrace all such alterations, modifications, and variations that fall within the scope of this application, including the appended claims.

What is claimed is:

1. A driver circuit comprising:
a high-side switch that is activated in response to a positive driver input signal to provide a positive output signal at a driver output;
a low-side switch that is activated in response to a negative driver input signal to provide a negative output signal at the driver output, the positive and negative driver input and output signals being relative to respective cross-over magnitudes; and
at least one impedance-matching device configured to activate the low-side switch in response to a positive signal reflection at the driver output and to activate the high-side switch in response to a negative signal reflection at the driver output.

2. The driver circuit of claim 1, wherein the at least one impedance-matching device has an associated resistance value that is substantially matched to an impedance of one of a load and an interconnecting transmission line coupled to the driver output.

3. The driver circuit of claim 2, wherein the high-side switch is activated to source current from the positive rail voltage to the driver output to substantially terminate the positive signal reflection and the low-side switch is activated to sink current from the driver output to the negative rail voltage to substantially terminate the negative signal reflection.

4. The driver circuit of claim 1, further comprising:
a high-side bias circuit configured to set a first bias voltage at a bias terminal of the high-side switch for activation of the high-side switch; and
a low-side bias circuit configured to set a second bias voltage at a bias terminal of the low-side switch for activation of the low-side switch.

5. The driver circuit of claim 4, wherein the high-side bias circuit comprises:
a first transistor interconnecting the bias terminal of the high-side switch and a negative rail voltage, the first transistor being biased by the input signal; and
a first current source interconnecting a positive rail voltage and the bias terminal of the high-side switch;
wherein the low-side bias circuit comprises:
a second transistor interconnecting the bias terminal of the low-side switch and the positive rail voltage; and
a second current source interconnecting the negative rail voltage and the bias terminal of the low-side switch;
wherein the first and second transistors are substantially configured as emitter-followers that are biased by the input signal.

6. The driver circuit of claim 1, wherein the at least one impedance-matching device comprises a first resistor interconnecting the high-side switch and the driver output and a second resistor interconnecting the low-side switch, the first and second resistors being configured to set a dead-band approximately centered at respective cross-over magnitude of the input signal, such that the neither the high-side switch nor the low-side switch provide the output signal upon the input signal residing in the dead-band, the dead-band having a positive magnitude and a negative magnitude relative to the input signal that are each associated with a magnitude of the output signal and a magnitude of the at least one impedance-matching device.

7. The driver circuit of claim 6, wherein the first resistor is configured to increase an activation bias magnitude of the high-side switch relative to the driver output and the second resistor is configured to decrease an activation bias magnitude of the low-side switch relative to the driver output.

8. A magnetic disk write system comprising the driver circuit of claim 1.

9. A driver circuit comprising:
a high-side switch that is activated in response to a positive driver input signal to provide a positive output signal at a driver output;
a low-side switch that is activated in response to a negative driver input signal to provide a negative output signal at the driver output, the positive and negative driver input and output signals being relative to respective cross-over magnitudes;
a first impedance-matching device interconnecting the high-side switch and the driver output; and
a second impedance-matching device interconnecting the low-side switch and the driver output.

10. The driver circuit of claim 9, wherein the first impedance-matching device is configured to increase an activation bias magnitude of the high-side switch relative to the driver output and the second impedance-matching device is configured to decrease an activation bias magnitude of the low-side switch relative to the driver output.

11. The driver circuit of claim 10, wherein the increased activation bias magnitude of the high-side switch and the decreased activation bias magnitude of the low-side switch defines a switching dead-band associated with the input signal that is approximately centered at the cross-over magnitude of the input signal, the dead-band having a positive magnitude and a negative magnitude relative to the input signal that are associated with a magnitude of the output signal and a magnitude of the first and second impedance-matching devices, respectively.

12. The driver circuit of claim 10, wherein at least one of the high-side switch and the low-side switch is deactivated at a given time in the absence of a signal reflection based on the increased activation bias magnitude of the high-side switch relative to the driver output and the decreased bias magnitude of the low-side switch relative to the driver output, thus substantially mitigating current flow from a positive rail voltage to a negative rail voltage through the high-side and low-side switches.

13. The driver circuit of claim 10, wherein a positive signal reflection received at the driver output decreases the activation bias magnitude of the high-side switch to activate the high-side switch to substantially terminate the positive signal reflection, and wherein a negative signal reflection received at the driver output increases the activation bias magnitude of the low-side switch to activate the low-side switch to substantially terminate the negative signal reflection.

14. The driver circuit of claim 9, further comprising:
a high-side bias circuit configured to set a first bias voltage at a bias terminal of the high-side switch for activation of the high-side switch; and
a low-side bias circuit configured to set a second bias voltage at a bias terminal of the low-side switch for activation of the low-side switch.

15. The driver circuit of claim 14, wherein the high-side bias circuit comprises:
a first transistor interconnecting the bias terminal of the high-side switch and a negative rail voltage, the first transistor being biased by the input signal; and
a first current source interconnecting a positive rail voltage and the bias terminal of the high-side switch;
wherein the low-side bias circuit comprises:
a second transistor interconnecting the bias terminal of the low-side switch and the positive rail voltage; and
a second current source interconnecting the negative rail voltage and the bias terminal of the low-side switch;
wherein the first and second transistors are substantially configured as emitter-followers that are biased by the input signal.

16. A driver circuit comprising:
means for providing a positive output signal at a driver output in response to a driver input signal having a magnitude that is greater than a first voltage, the first voltage being greater than an input cross-over voltage;
means for providing a negative output signal at the driver output in response to the driver input signal having a magnitude that is less than a second voltage, the second voltage being less than the input cross-over voltage, the positive and negative output signals being relative to an output cross-over voltage; and
means for substantially matching an output impedance of the driver output with one of a load and an interconnecting transmission line and for setting respective magnitudes of the first voltage and the second voltage.

17. The driver circuit of claim 16, wherein the means for substantially matching the output impedance is configured to activate the means for providing the positive output signal in response to a negative signal reflection at the driver output and to activate the means for providing the negative output signal in response to a positive signal reflection.

18. The driver circuit of claim 17, further comprising:
means for setting a first bias voltage associated with the means for providing the positive output signal; and
means for setting a second bias voltage associated with the means for providing the negative output signal.

19. The driver circuit of claim 17, wherein the means for substantially matching the output impedance comprises first means for providing resistance between the means for providing the positive output signal and the driver output and second means for providing resistance between the means for providing the negative output signal and the driver output.

20. The driver circuit of claim 19, wherein the first means for providing resistance is configured to increase an activation voltage associated with the means for providing the positive output signal relative to the driver output and the second means for providing resistance is configured to decrease an activation voltage associated with the means for providing the negative output signal relative to the driver output.
